(19) United States
(12) Patent Application Publication
(10) Pub. No.: US 2020/0203396 A1
(43) Pub. Date: Jun. 25, 2020

(54) METHOD FOR MANUFACTURING DISPLAY APPARATUS, DISPLAY APPARATUS, AND TERMINAL

(71) Applicant: BOE Technology Group Co., Ltd., Beijing (CN)

(72) Inventor: Lu Liu, Beijing (CN)

(21) Appl. No.: 16/612,798

(22) PCT Filed: May 11, 2018
(86) PCT No.: PCT/CN2018/086605

§ 371 Date: Nov. 12, 2019

(30) Foreign Application Priority Data
May 12, 2017 (CN) 201710334942.7

(51) Int. Cl. H01L 27/12; G02F 1/1333; G02F 1/1339

(52) U.S. Cl. CPC H01L 27/1262; G02F 1/133305; H01L 27/1218; G02F 1/1339; H01L 27/1288

(57) ABSTRACT

Provided are a method for manufacturing a display apparatus, a display apparatus, and a terminal, pertaining to the field of displays. The display apparatus includes a flexible substrate, the flexible substrate including a first face and a second face that are opposite to each other, a display element being on the first face, a protective film layer being on the second face. The method includes: providing a mask; and irradiating towards one side of the protective film layer away from the flexible substrate through the mask by using light to form a groove on the protective film layer, such that the flexible substrate is bendable in a region corresponding to the groove.

This application is a 371 of PCT Application Serial No. PCT/CN2018/086605, filed on May 11, 2018, which claims priority to Chinese Patent Application No. 201710334942.7, filed on May 12, 2017 and entitled “METHOD FOR PROCESSING DISPLAY DEVICE, AND DISPLAY APPARATUS”, the entire contents of which are incorporated herein by reference.

### TECHNICAL FIELD

The present disclosure relates to the field of displays, and particularly to a method for manufacturing a display apparatus, a display apparatus, and a terminal.

### BACKGROUND

Flexible display apparatuses include flexible substrates. The flexible substrate has a display region and a wiring region. The wiring region has a greater width. Therefore, the manufactured display device has a wider frame.

At present, displays with a narrow frame are desired in the market. To accommodate such demands, the wiring region may be bent, and folded to the back face of the display region to reduce the width of the wiring region. In this way, displays with a narrower frame may be manufactured. However, yield of the folded displays still needs to be improved.

### SUMMARY

In an aspect, there is provided a method for manufacturing a display apparatus. The display apparatus comprises a flexible substrate, the flexible substrate comprising a first face and a second face that are opposite to each other, a display element being on the first face, a protective film layer being on the second face; wherein the method comprises:

providing a mask; and

irradiating towards one side of the protective film layer away from the flexible substrate through the mask by using light to form a groove on the protective film layer.

Optionally, the irradiating towards one side of the protective film layer away from the flexible substrate through the mask by using light to form a groove on the protective film layer comprises:

irradiating one side of the protective film layer away from the flexible substrate through the mask by using a laser beam to form the groove on the protective film layer.

Optionally, a transmittance of the mask for the laser beam gradually decreases along a direction away from a center of the mask.

Optionally, the mask as a plurality of gray scale regions arranged along a direction away from a center of the mask, a transmittance of the plurality of gray scale regions for the laser beam gradually decreasing along an arrangement direction of the plurality of gray scale regions.

Optionally, the laser beam is an ultraviolet UV laser beam.

Optionally, the laser beam is a carbon dioxide CO₂ laser beam.

Optionally, the irradiating towards one side of the protective film layer away from the flexible substrate through the mask by using light to form a groove on the protective film layer comprises:

forming the groove on the protective film layer by a patterning process.

Optionally, a width of the groove in a direction parallel to the flexible substrate and away from the display element is greater than or equal to 0.8 mm, and less than or equal to 2 mm.

Optionally, a connection layer is between the flexible substrate and the protective film layer, and the groove has a depth that is less than a sum of a thickness of the protective film layer and a thickness of the connection layer.

Optionally, the irradiating towards one side of the protective film layer away from the flexible substrate through the mask by using light to form a groove on the protective film layer comprises:

irradiating one side of the protective film layer away from the flexible substrate through the mask by using a laser beam to form the groove on the protective film layer, an inner side face of the groove being arc-shaped;

wherein, a transmittance of the mask for the laser beam gradually decreases along a direction away from a center of the mask;

a connection layer is between the flexible substrate and the protective film layer, the groove has a depth that is less than a sum of a thickness of the protective film layer and a thickness of the connection layer; and

the first face of the flexible substrate includes a bending region, an orthographic projection of the groove on the first face overlapping the bending region, and the first face of the flexible substrate includes a wiring region, the bending region being within the wiring region.

In another aspect, there is provided a display apparatus, comprising:

a flexible substrate, the flexible substrate comprising a first face and a second face that are opposite to each other, a display element being on the first face, a protective film layer being on the second face;

wherein a groove is on a face of the protective film layer away from the flexible substrate.

Optionally, the first face of the flexible substrate includes a bending region, an orthographic projection of the groove on the first face overlapping the bending region.

Optionally, the first face of the flexible substrate includes a wiring region, the bending region being within the wiring region.

Optionally, an inner side face of the groove is arc-shaped.

Optionally, an inner side face of the groove is step-shaped.

Optionally, the groove is a rectangular groove.

Optionally, a width of the groove in a direction parallel to the flexible substrate and away from the display element is greater than or equal to 0.8 mm, and less than or equal to 2 mm.

Optionally, a connection layer is between the flexible substrate and the protective film layer, and the groove has a depth that is less than a sum of a thickness of the protective film layer and a thickness of the connection layer.

Optionally, the first face of the flexible substrate includes a bending region, an orthographic projection of the groove on the first face overlapping the bending region, and the first face of the flexible substrate includes a wiring region, the bending region being within the wiring region; and

a connection layer is between the flexible substrate and the protective film layer, the groove has a depth that is less than a sum of a thickness of the protective film layer and a thickness of the connection layer, and the inner side face of the groove is arc-shaped.

In yet another aspect, there is provided a terminal, comprising a display apparatus. The display apparatus comprises a flexible substrate, the flexible substrate comprising a first face and a second face that are opposite to each other, a display element being on the first face, a protective film layer being on the second face; wherein a groove is on a face of the protective film layer away from the flexible substrate.

### BRIEF DESCRIPTION OF THE DRAWINGS

FIG. 1 is a schematic structural diagram of a display apparatus according to an embodiment of the present disclosure;

FIG. 2 is a schematic exploded structural diagram of a display apparatus according to an embodiment of the present disclosure;

FIG. 3 is a schematic structural diagram of a display apparatus according to an embodiment of the present disclosure;

FIG. 4 is a schematic structural diagram of another display apparatus according to an embodiment of the present disclosure;

FIG. 5 is a schematic structural diagram of still another display apparatus according to an embodiment of the present disclosure;

FIG. 6 is a flowchart of a method for manufacturing a display apparatus according to an embodiment of the present disclosure;

FIG. 7 is a flowchart of another method for manufacturing a display apparatus according to an embodiment of the present disclosure;

FIG. 8 is a schematic structural diagram of yet still another display apparatus according to an embodiment of the present disclosure;

FIG. 9 is a schematic flowchart of still yet another method for manufacturing a display apparatus according to an embodiment of the present disclosure;

FIG. 10 is a schematic structural diagram of a mask according to an embodiment of the present disclosure;

FIG. 11 is a schematic diagram of a relationship between the mask and transmittance according to an embodiment of the present disclosure;

FIG. 12 is a schematic diagram of bending a display apparatus according to an embodiment of the present disclosure;

FIG. 13 is a flowchart of yet still another method for manufacturing a display apparatus according to an embodiment of the present disclosure;

FIG. 14 is a schematic diagram of etching a photoresist according to an embodiment of the present disclosure;

FIG. 15 is a schematic diagram of covering a photoresist according to an embodiment of the present disclosure;

FIG. 16 is a flowchart of yet still another method for manufacturing a display apparatus according to an embodiment of the present disclosure;

FIG. 17 is a schematic structural diagram of yet still another display apparatus according to an embodiment of the present disclosure; and

FIG. 18 is a schematic diagram of adhering a first protective film layer and a second protective film layer according to an embodiment of the present disclosure.

### DETAILED DESCRIPTION

The embodiments of the present disclosure will be described in details hereinafter with reference to the accompanying drawings.

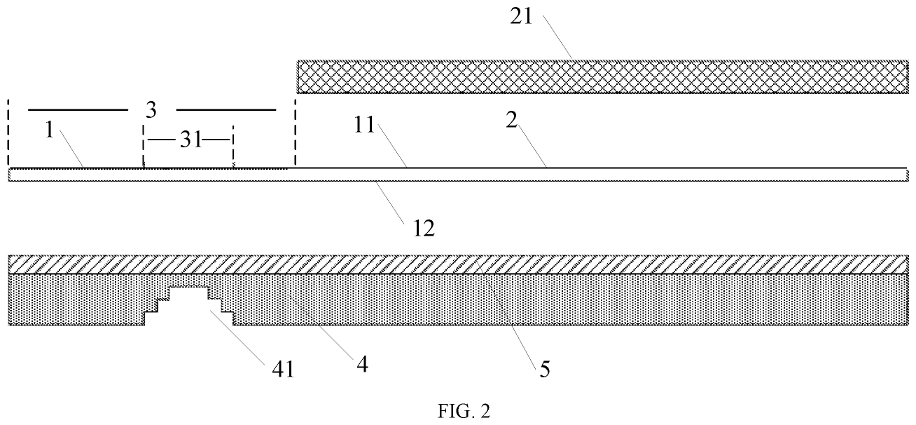

An embodiment of the present disclosure provides a display apparatus. Referring to FIG. 2 and FIG. 2, the display apparatus includes:

a flexible substrate 1, wherein the flexible substrate 1 includes a first face 11 and a second face 12 that are opposite to each other. A display region 2 and a wiring region 3 are on the first face 11. A display element 21 is on the display region 2. A protective film layer 4 is on the second face 12. The material of the flexible substrate may include Polyimide (PI).

The protective film layer 4 and the flexible substrate 1 are connected via a connection layer 5. The material of the connection layer 5 may include an adhesive or the like materials, for example, Optically Clear Adhesive (OCA). The protective film layer 4 has a thickness that is 5 to 15 times that of the flexible substrate 1. The flexible substrate 1 has flexibility, and may be made of a material having flexibility, such as plastic, rubber or the like.

The wiring region 3 is internally provided with a bending region 31. Since the protective film layer has a greater thickness which is generally several times that of the flexible substrate 1, when the bending region 31 is bent, the protective film layer 4 may exert a great stress to metal wires in the wiring region 3, which causes the metal wires to break.

In the embodiment of the present disclosure, a position facing the bending region 31 of the protective film layer 4 is provided with a groove 41. That is, an orthographic projection of the groove 41 on the first face 11 overlaps the bending region. Referring to FIG. 2, the wiring region 3 is bent along the groove 41, such that the wiring region 3 is bent to a back face of the display region 2, thereby forming a display apparatus. Due to presence of the groove 41, during bending, the stress exerted by the protective film layer 4 to the metal wires in the wiring region 3 may be reduced, and breakage of the metal wires may be prevented.

A distance from the bending region 31 in the wiring region 3 to the display region 2 may be less than or equal to 2 mm. In this way, the manufactured display apparatus may have a frame that is less than or equal to 2 mm.

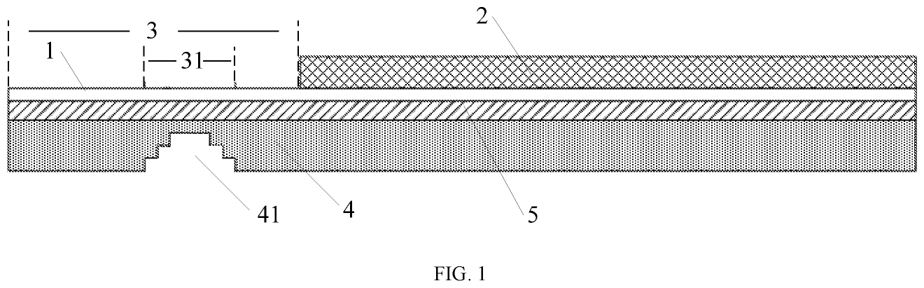

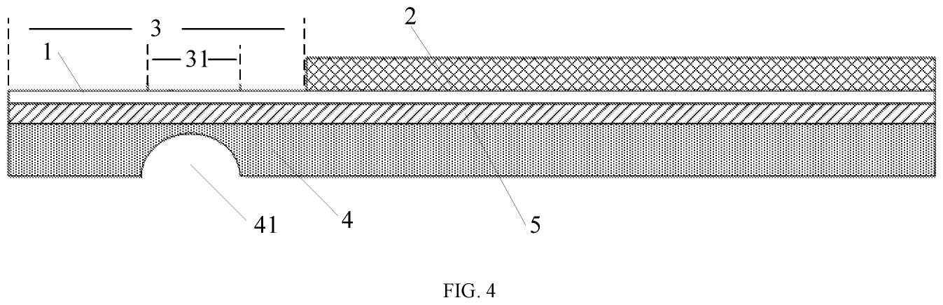

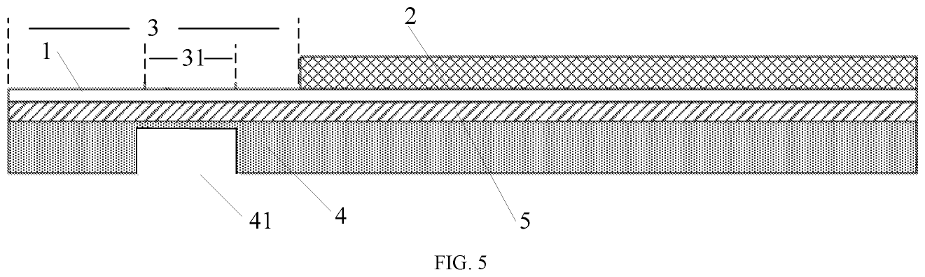

The width of the groove 41 ((the width may refer to the maximum width of the groove 41) in the direction f parallel to the flexible substrate 1 and away from the display element 21 may be greater than or equal to 0.8 mm, and less than or equal to 2 mm. For example, the width of the groove 41 may be 0.8 mm, 1 mm, 1.2 mm, 1.4 mm, 1.6 mm, 1.8 mm, 2 mm or the like. Referring to FIG. 1, FIG. 4 or FIG. 5, the groove 41 may have an arc-shaped, step-shaped or the like inner side face, or the groove 41 may have a rectangular section.

The groove 41 may have a depth that is less than a sum of the thickness of the protective film layer 4 and a thickness of the connection layer 5. That is, the bottom of the groove 41 may be the connection layer 5 or a film layer having a small thickness.

Referring to the display apparatus as illustrated in FIG. 2, the protective film layer 4 of the display apparatus includes a first portion 42 and a second portion 43. The first portion 42 is the protective film layer 4 facing the bending region 31. The second portion 43 is the protective film layer 4 of the remaining region except the first portion 42 in the protective film layer 4. The first portion 42 has a thickness that is less than that of the second portion 43.

The thickness of the first portion 42 may be less than the thickness of the protective film layer 4, or may be 0.

In this embodiment of the present disclosure, since the protective film layer facing the bending region in the wiring region is internally provided with a groove, when the wiring region is bent along the groove, a stress exerted by the protective film layer to the metal wires on the surface of the wiring region is reduced, and thus the metal wires on the surface of the wiring region are prevented from breakage when the wiring region is bent, thereby improving yield of the display apparatuses.

In this embodiment of the present disclosure, the position of the groove is not limited, and the groove may be formed at a position corresponding to the bendable region of the flexible substrate, to improve bending yield.

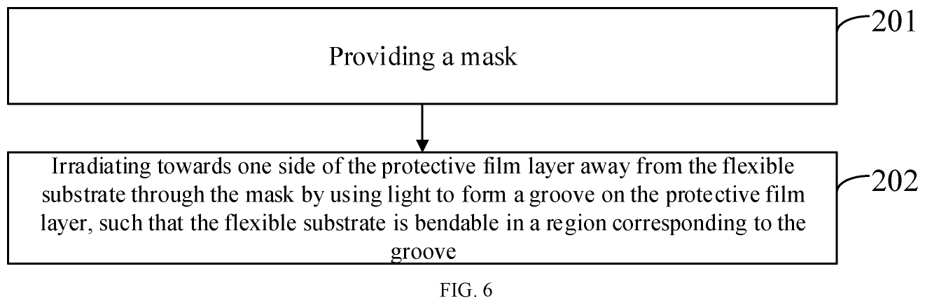

Referring to FIG. 6, an embodiment of the present disclosure provides a method for manufacturing a display apparatus. The display apparatus includes a flexible substrate. The flexible substrate includes a first face and a second face that are opposite to each other. A display element is on the first face. A protective film layer is on the second face. The method includes following steps.

In step 201, a mask is provided.

In step 202, irradiation is given towards one side of the protective film layer away from the flexible substrate through the mask by using light to form a groove on the protective film layer, such that the flexible substrate is bendable in a region corresponding to the groove.

In this embodiment of the present disclosure, since the irradiation is given towards one side of the protective film layer through the mask by using light to form a groove, when the flexible substrate is bent along the groove, a stress exerted by the protective film layer to the metal wires on the surface of the flexible substrate is reduced, and thus the metal wires are prevented from breakage during bending, thereby improving yield of the display apparatuses.

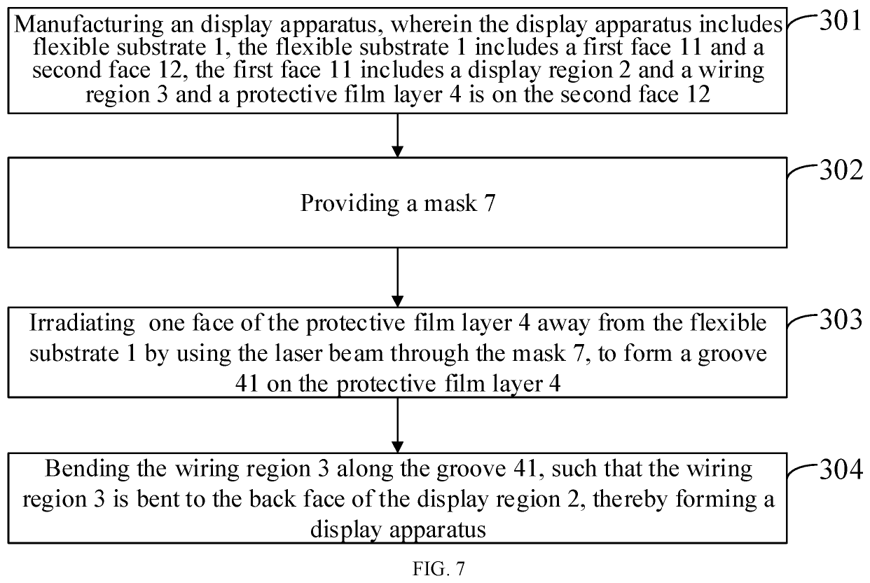

Referring to FIG. 7, an embodiment of the present disclosure provides a method for manufacturing a display apparatus. The method includes following steps.

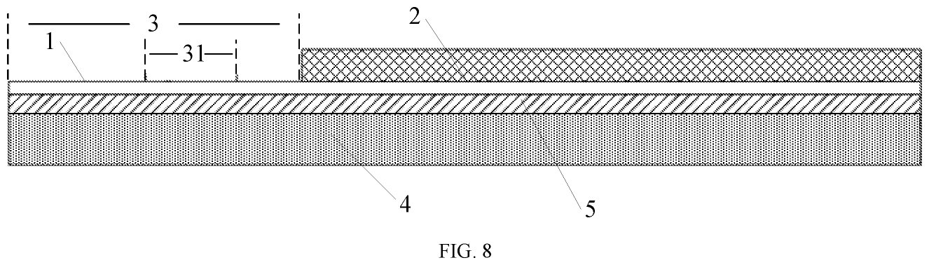

In step 301, a display apparatus is manufactured. As illustrated in FIG. 2 and FIG. 8, the display apparatus includes a flexible substrate 1. The flexible substrate 1 includes a first face 11 and a second face 12. The first face 11 includes a display region 2 and a wiring region 3. A protective film layer 4 is on the second face 12.

The display region 2 includes an array substrate, and may further include a liquid crystal layer, a color film substrate, and the like display elements. Various lead wires, for example, metal wires are arranged on the surface of the wiring region 3. The protective film layer 4 and the flexible substrate 1 are connected via a connection layer 5, wherein the material of the connection layer 5 may include materials as an adhesive. The flexible substrate 1 has flexibility and is bendable, and may be made of a material having flexibility, such as plastic, rubber or the like.

Referring to FIG. 8, the wiring region 3 includes a bending region 31, wherein a distance from the bending region 31 to the display region 2 may be less than or equal to 2 mm, and the wiring region 3 may be bent towards the back face of the display region 2 within the bending region 31.

In step 302, a mask 7 is provided.

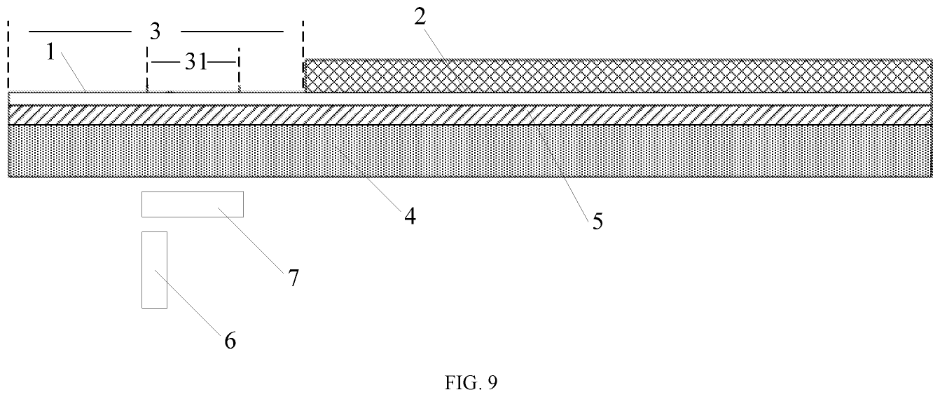

As illustrated in FIG. 9, the mask 7 is arranged below the protective film layer 4 facing the bending region 31, and a light source is arranged below the mask 7.

The light source 6 may be a laser, wherein the laser may be an ultraviolet solid laser or a carbon dioxide gas laser or the like, and a laser beam emitted by the laser may be an ultraviolet (UV) laser beam or a carbon dioxide (CO₂) laser beam or the like.

Optionally, the transmittance for the light source 6 at the center of the mask 7 is greater than that for the light source 6 at the edge of the mask 7, and the transmittance of the mask 7 for the laser beam gradually decreases along the direction away from the center of the mask 7. Alternatively, the transmittances for the laser beam in various parts in the mask 7 are equal.

Where the transmittances for the laser beam in various parts in the mask 7 are different, since the transmittance for the laser beam in the mask 7 gradually increases from the edge of the mask 7 to the center of the mask 7, the transmitting degrees for the laser beam in various parts in the mask 7 are different. The transmitting degree for the laser beam at the edge of the mask 7 is minimum, and the transmitting degree for the laser beam at the center of the mask 7 is maximum, such that the irradiation of the laser beam to the protective film layer may be controlled via the mask, and a shaping effect of the groove is improved.

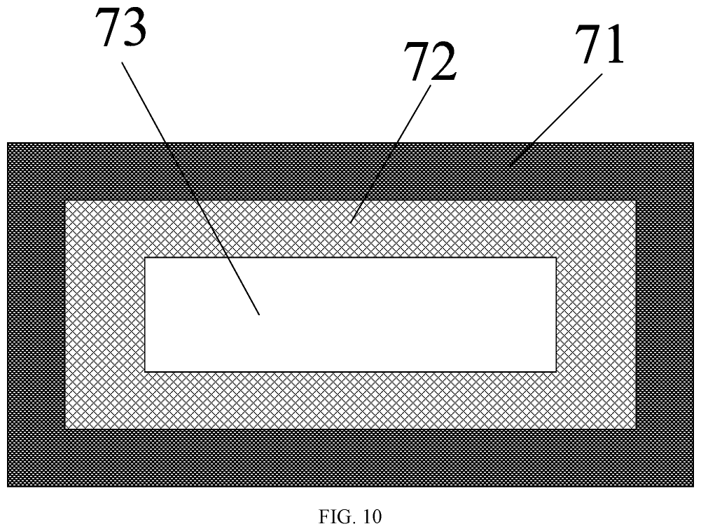

Referring to FIG. 10, a plurality of gray scale regions 71, 72 and 73 are arranged on the mask 7 in the direction away from the center of the mask 7. The transmittance of the plurality of gray scale regions for the laser beam gradually decreases along the arrangement direction of the plurality of gray scale regions (i.e., the direction away from the center of the mask 7). In FIG. 10, the surface of the mask 7 may be divided into multiple turns of gray scale regions having a common center. Each turn of gray scale region has a different gray tone. The greater the gray tone of the gray scale region, the smaller the transmittance for the laser beam in the gray scale region. On the contrary, the smaller the gray tone of the gray scale region, the greater the transmittance for the laser beam in the gray scale region.

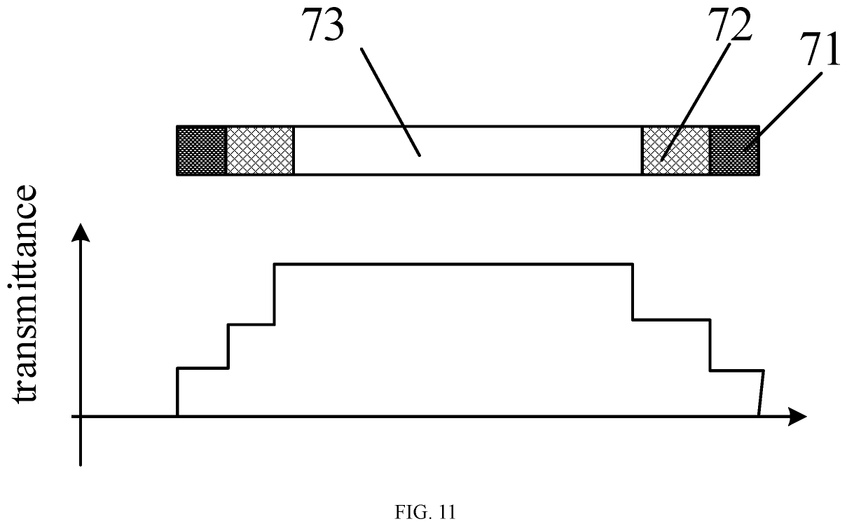

For example, referring to FIG. 11, the mask 7 includes a first gray scale region 71, a second gray scale region 72 and a third gray scale region 73 that have a common center. The second gray scale region 72 is between the first gray scale region 71 and the third gray scale region 73.

The first gray scale region 71 is at the edge of the mask 7, and has a greatest gray tone and a smallest transmittance for the laser beam. The second gray scale region 72 is between the first gray scale region 71 and the third gray scale region 73. The gray tone of the second gray scale region 72 is less than that of the first gray scale region 71, and the transmittance for the laser beam in the second gray scale region 72 is greater than that for the laser beam in the first gray scale region 71. The third gray scale region 73 is at the center of the mask 7, and has a smallest gray tone and a greatest transmittance for the laser beam.

In this embodiment, the mask 7 may be a step half tone mask or the like.

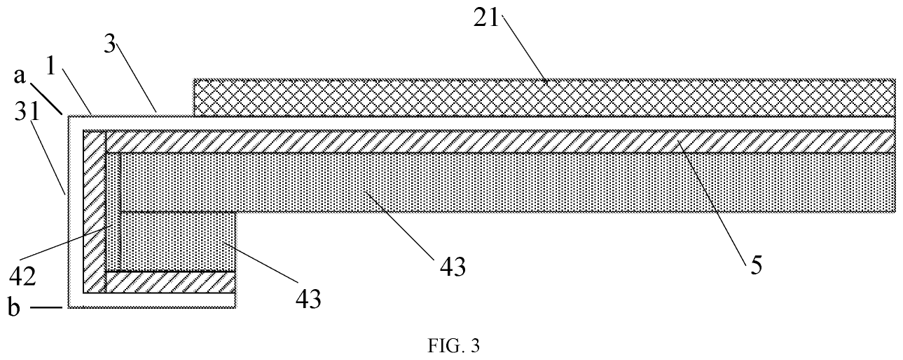

In step 303, as illustrated in FIG. 1 or FIG. 3, one face of the protective film layer 4 away from the flexible substrate 1 is irradiated by using the laser beam through the mask 7, to form a groove 41 on the protective film layer 4.

Optionally, a laser beam is emitted to the mask 7 by using the light source 6, such that the laser beam is irradiated on the protective film layer 4 facing the bending region 31 through the mask 7 and the protective film layer is ablated, to cut the groove 41 on the protective film layer 4.

In this step, the mask 7 may be irradiated back and forth by using the laser along the mask 7, until the groove 41 is formed on the protective film layer 4. Alternatively, a laser intensity emitted by the laser is improved, such that the laser irradiates the mask 7 for one time along the mask 7, to form the groove 41 on the protective film layer 4.

Where the transmittances for the laser beam in various parts in the mask 7 are different, since the transmittance for the laser beam in the mask 7 gradually increases from the edge of the mask 7 to the center of the mask 7, the intensities of the laser beams irradiated to different regions on the protective film layer 4 are different, and therefore, an inner side face of the formed groove 41 may be step-shaped or arc-shaped.

If the mask 7 includes more gray scale regions, the inner side face of the groove 41 formed by using the mask 7 is smoother and is more arch-shaped. On the contrary, if the mask 7 includes fewer gray scale regions, the inner side face of the groove 41 formed by using the mask 7 is more apparently step-shaped.

Where the transmittances for the laser beam in various parts in the mask 7 are equal, the laser intensities of the laser beams irradiated to different regions on the protective film layer 4 are equal, and therefore, a section of the formed groove 41 cut by a plane parallel to the flexible substrate 1 is rectangular. That is, the groove 41 is a rectangular groove.

Optionally, when the formed groove 41 has a rectangular section, step 302 is an optional step. That is, the mask 7 may be arranged between the laser and the protective film layer 4, or the mask 7 may be not arranged between the laser 6 and the protective film layer 4.

When the mask 7 is not arranged between the laser 6 and the protective film layer 4, the laser beam emitted by the laser is directly irradiated to the protective film layer 4, to form the groove 41 having a rectangular section.

Optionally, the groove 41 may have a width that is greater than or equal to 0.8 mm, and less than or equal to 2 mm. For example, the width of the groove 41 may be 0.8 mm, 1 mm, 1.2 mm, 1.4 mm, 1.6 mm, 1.8 mm, 2 mm or the like.

Optionally, the groove 41 may have a depth that is less than a sum of the thickness of the protective film layer 4 and a thickness of the connection layer 5. That is, the bottom of the groove 41 may be the connection layer 5 or a film layer having a small thickness.

In step 304, as illustrated in FIG. 2, the wiring region 3 is bent along the groove 41, such that the wiring region 3 is bent to the back face of the display region 2, thereby forming a display apparatus.

When the groove 41 has a rectangular section, the wiring region 3 is bent along the groove 41. Since the thickness of the film layer at the bottom of the groove 41 reduces, the stress to the metal wires arranged on the surface of the wiring region reduces. However, referring to FIG. 3, when the wiring region 3 is bent, bending parts a and b with a right angle or an approximate right angle are formed on the surface of the wiring region 3, and the stress suffered by the metal wires at the bending parts a and b is still greater.

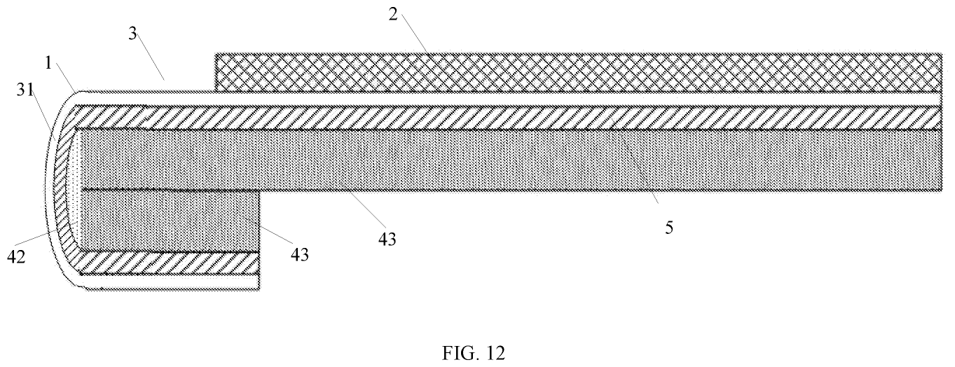

To solve this problem, the groove 41 without a rectangular section may be formed, and instead, the groove 41 with an arc-shaped or step-shaped side face may be formed. That is, the formed groove 41 may be like the groove as illustrated in FIG. 1 and FIG. 3. Referring to FIG. 12, when the wiring region 3 is bent along the groove 41, a curve surface may be formed on the surface of the wiring region 3, such that the stress suffered by the metal wires in various parts on the surface of the wiring region 3 greatly reduces.

Referring to the display apparatus as illustrated in FIG. 3, the protective film layer 4 of the display apparatus includes a first portion 42 and a second portion 43. The first portion 42 is the protective film layer 4 facing the bending region 31. The second portion 43 is the remaining portion except the first portion 41 in the protective film layer 4. The first portion 42 has a thickness that is less than that of the second portion 43.

The thickness of the first portion 42 may be less than the thickness of the protective film layer 4, or may be 0.

Since the bent wiring region 3 has a smaller width, the display apparatus has a smaller frame, such that a display apparatus with a frame that is less than or equal to 2 mm can be manufactured.

Optionally, the protective film layer 4 may be made of organic materials, such as polyethylene terephthalate (PET), PI, Polyethylene naphthalate two formic acid glycol ester (PEN), or the like.

In the embodiment of the present disclosure, since the protective film layer facing the bending region in the wiring region is provided with a groove, when the wiring region is bent along the groove, the stress exerted by the protective film layer to the metal wires on the surface of the wiring region is reduced, and thus the metal wires on the surface of the wiring region are prevented from breakage when the wiring region is bent, thereby improving yield of the manufactured display apparatuses. Further, since the side face of the groove is arc-shaped or step-shaped, when the wiring region is bent along the groove, a curved surface may be formed on the surface of the wiring region, such that the stress suffered by the metal wires in various parts on the surface of the wiring region is greatly reduced, and yield of the manufactured display apparatuses is further improved.

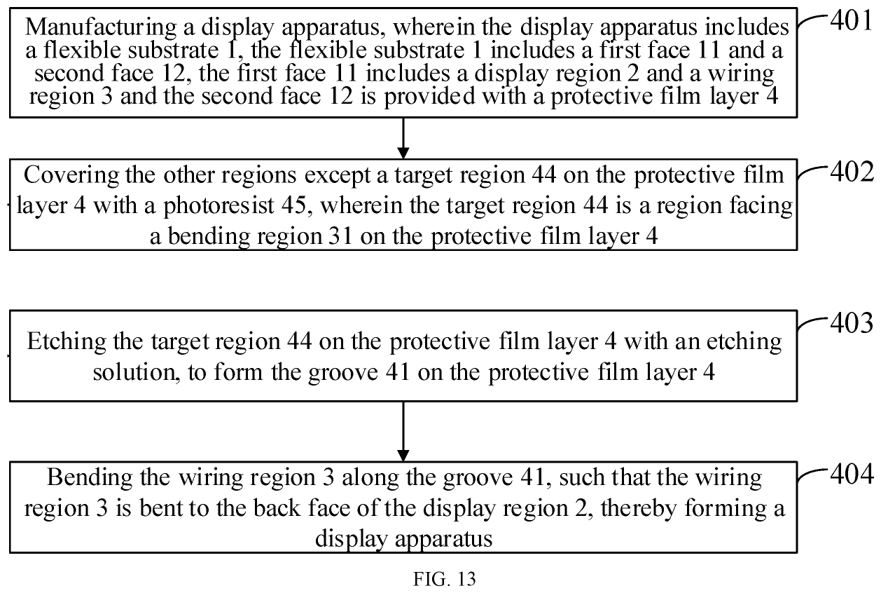

Referring to FIG. 13, an embodiment of the present disclosure provides a method for manufacturing a display apparatus. The method includes the following steps.

In step 401, a display apparatus is manufactured. As illustrated in FIG. 8, the display apparatus includes a flexible substrate 1. The flexible substrate 1 includes a first face 11 and a second face 12. The first face 11 includes a display region 2 and a wiring region 3. A protective film layer 4 is on the second face 12.

The display region 2 includes an array substrate, and may further include a liquid crystal layer, a color film substrate, and the like display elements. Metal wires are arranged on the surface of the wiring region 3. The protective film layer 4 and the flexible substrate 1 are connected via a connection layer 5. The material of the connection layer 5 may include such materials as an adhesive. The flexible substrate 1 has flexibility and is bendable, and may be made of a material having flexibility, such as plastic, rubber or the like.

Referring to FIG. 8, a bending region 31 is within the wiring region 3. The distance from the bending region 31 to the display region 2 may be less than or equal to 2 mm, and the wiring region 3 may be bent towards the back face of the display region 2 within the bending region 31.

Hereinafter, a photoresist 45 may be formed on the protective film layer 4, and a groove 41 is formed on the protective film layer 4 by a patterning process. The patterning process may include forming photoresist, performing exposure and developing on the photoresist, etching, photoresist stripping and the like.

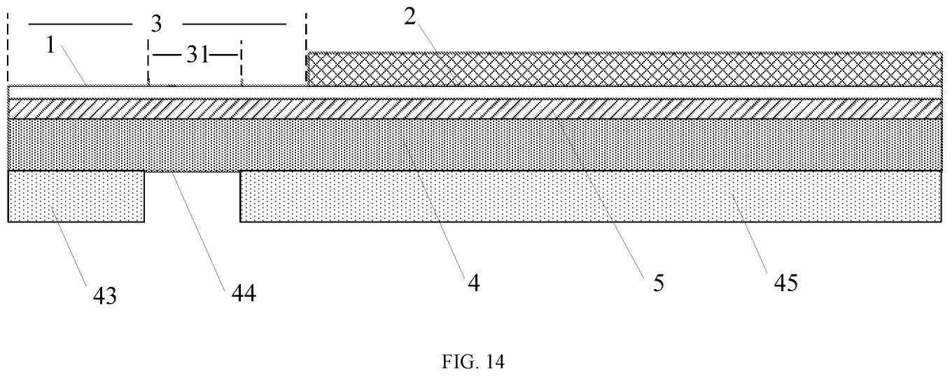

In step 402, referring to FIG. 14, the other regions except a target region 44 on the protective film layer 4 is covered with a photoresist 45. The target region 44 is a region facing a bending region 31 on the protective film layer 4.

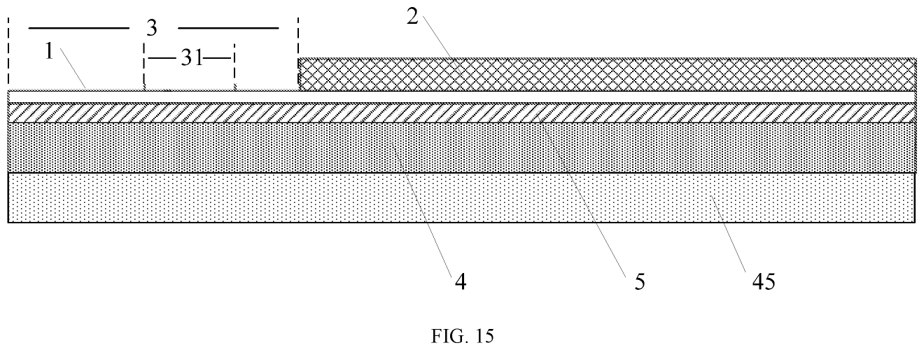

Optionally, referring to FIG. 15, the surface of the protective film layer 4 may be covered with a layer of the photoresist, and a mask is provided. The photoresist 45 on the target region 44 is exposed via the mask, and the photoresist 45 on the target region 44 may change to a carboxylic acid substance after being exposed. Referring to FIG. 14, the substance on the target region 44 is dissolved with a developing solution, to expose the protective film layer 4 in the target region 44.

In step 403, referring to FIG. 3, the target region 44 on the protective film layer 4 is etched with an etching solution, to form the groove 41 on the protective film layer 4.

In step 404, as illustrated in FIG. 2, the wiring region 3 is bent along the groove 41, such that the wiring region 3 is bent to the back face of the display region 2, thereby forming a display apparatus.

Optionally, the protective film layer 4 may be made of an inorganic material, for example, silicon nitride (SiNₓ) or silicon oxide (SiOₓ) or the like

In the embodiment of the present disclosure, since the groove is formed by etching with an etching solution on protective film layer facing the bending region, when the wiring region is bent along the groove, the stress exerted by the protective film layer to the metal wires arranged on the surface of the wiring region is reduced, and thus the metal wires on the surface of the wiring region are prevented from breakage when the wiring region is bent, thereby improving yield of the manufactured display apparatuses.

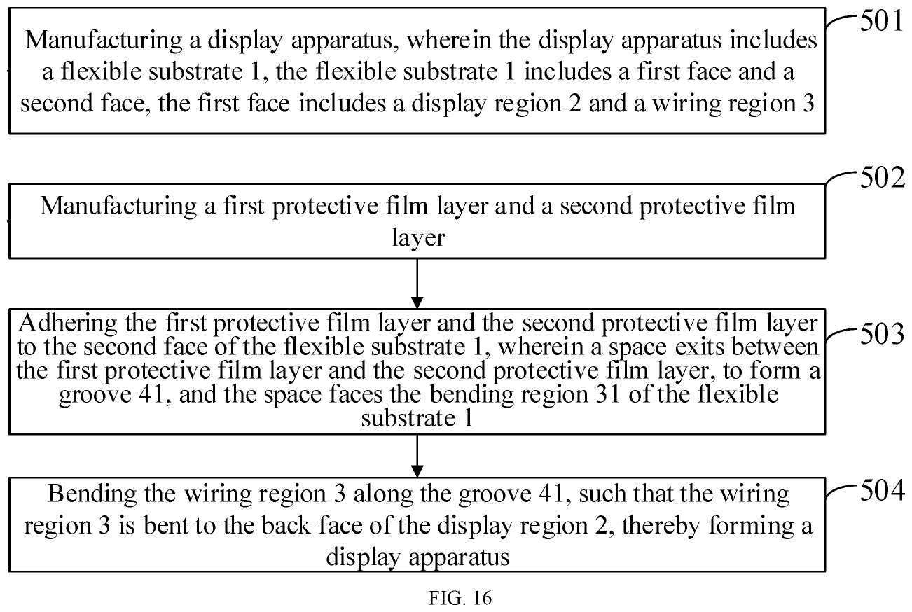

Referring to FIG. 16, an embodiment of the present disclosure provides a method for manufacturing a display apparatus. The method includes following steps.

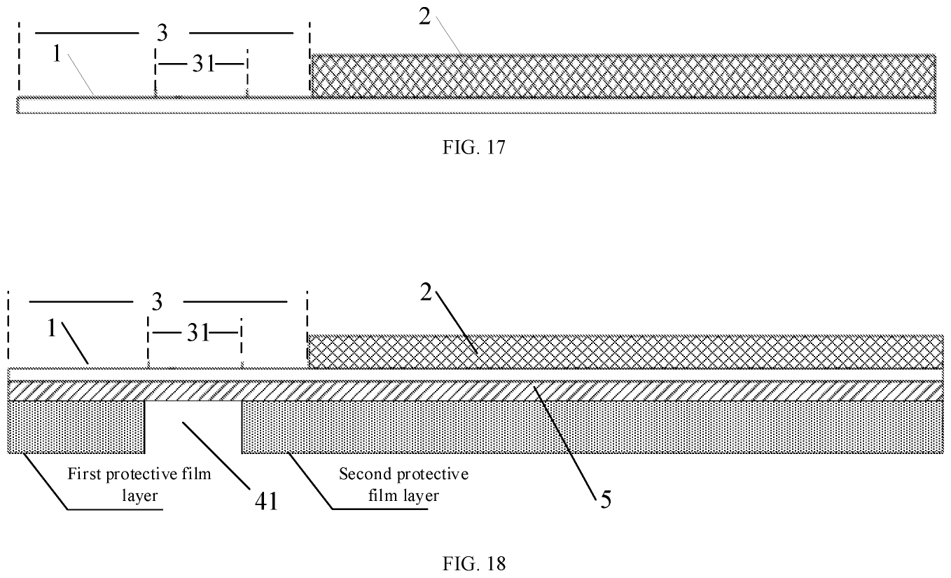

In step 501, a display apparatus is manufactured. As illustrated in FIG. 17, the display apparatus includes a flexible substrate 1. The flexible substrate 1 includes a first face and a second face that are opposite to each other. The first face is provided with a display region 2 and a wiring region 3.

The display region 2 includes an array substrate, and may further include a liquid crystal layer, a color film substrate, and the like display elements. Metal wires are arranged on the surface of the wiring region 3. The flexible substrate 1 has flexibility and is bendable, and may be made of a material having flexibility, such as plastic, rubber or the like.

Referring to FIG. 17, a bending region 31 is within the wiring region 3. The distance from the bending region 31 to the display region 2 may be less than or equal to 2 mm, and the wiring region 3 may be bent towards the back face of the display region 2 within the bending region 31.

In step 502, a first protective film layer and a second protective film layer are manufactured.

Optionally, a protective film layer may be manufactured on a plane, and then the protective film layer is cut to obtain a first protective film layer and a second protective film layer that have a desired size.

In step 503, the first protective film layer and the second protective film layer are adhered to the second face of the flexible substrate 1. A space exits between the first protective film layer and the second protective film layer, to form a groove 41, and the space faces the bending region 31 of the flexible substrate 1.

Optionally, referring to FIG. 18, a connection layer 5 configured to connect the first protective film layer and the second protective film layer may be arranged on the second face of the flexible substrate 1. The connection layer 5 may be made of such materials as an adhesive. Afterwards, the first protective film layer and the second protective film layer are adhered to the connection layer 5.

In step 504, as illustrated in FIG. 2, the wiring region 3 is bent along the groove 41, such that the wiring region 3 is bent to the back face of the display region 2, thereby forming a display apparatus.

In the embodiment of the present disclosure, when the first protective film layer and the second protective film layer are adhered to the second face of the flexible substrate, a space exits between the first protective film layer and the second protective film layer to form a groove. As such, when the wiring region is bent along the groove, a stress exerted by the protective film layer to the metal wires arranged on the surface of the wiring region is reduced, and thus the metal wires on the surface of the wiring region are prevented from breakage when the wiring region is bent, thereby improving yield of the display apparatuses.

An embodiment of the present disclosure provides a display apparatus. Referring to FIG. 2, FIG. 3, FIG. 4 and FIG. 5, the display apparatus includes: a flexible substrate 1. The flexible substrate 1 includes a first face 11 and a second face 12 that are opposite to each other. A display element 21 is on the first face 11, and a protective film layer 4 is on the second face 12.

A groove is on the protective film layer 4, and the flexible substrate 1 is bendable in a region corresponding to the groove 41.

Optionally, the width of the groove 41 in the direction f parallel to the flexible substrate 1 and away from the display element 21 is greater than or equal to 0.8 mm, and less than or equal to 2 mm.

Optionally, the groove 41 has a depth that is less than a sum of a thickness of the protective film layer 4 and a thickness of a connection layer 5. The connection layer 5 is configured to connect the substrate 1 and the protective film layer 4.

Optionally, an inner side face of the groove 41 is arc-shaped or step-shaped, and a section of the groove 41 cut by a plane parallel to the flexible substrate 1 is rectangular (That is, the groove is a rectangular groove).

Optionally, the first face 11 of the flexible substrate 1 includes a bending region 31, and an orthographic projection of the groove 41 on the first face 11 overlaps the bending region 31.

Optionally, the first face 11 of the flexible substrate 1 includes a wiring region 3, and the bending region 31 is within the wiring region 3.

In the embodiment of the present disclosure, since the protective film layer is provided with a groove and the flexible substrate is bendable in a region corresponding to the groove, when the flexible substrate is bent along the groove, a stress exerted by the protective film layer to the metal wires arranged on the surface of the flexible substrate is reduced, and thus the metal wires on the surface of the flexible substrate are prevented from breakage when the flexible substrate is bent, thereby improving yield of the manufactured display apparatuses.

The present disclosure further provides a terminal. The terminal includes any of the display apparatuses provided in the above embodiments. The terminal may be a device with a display function, such as a mobile phone, a tablet computer, a smart wearable device or a laptop computer.

The size of the layers and regions may be exaggerated for clarity of illustration in the accompanying drawings of the embodiments of the present disclosure. In addition, it should be understood that when an element or layer is referred to be “on” another element or layer, the element or layer may be directly another element, or an intermediate layer may exist there between. Additionally, it should be understood that when an element or layer is referred to be “under” another element or layer, the element or layer may be directly under another element, or more than one intermediate elements or layers may exist there between. Moreover, it should be understood that when a layer or an element is referred to be “between” two layers or two elements, the layer or element may be the only layer between the two layers or the two elements, or more than one intermediate layer or element may exit. Reference numerals in the whole text indicate similar elements.

The foregoing descriptions are merely optional embodiments of the present disclosure, and are not intended to limit the present disclosure. Within the spirit and principles of the disclosure, any modifications, equivalent substitutions, improvements, etc., are within the protection scope of the present disclosure.

What is claimed is:

1. A method for manufacturing a display apparatus, the display apparatus comprising a flexible substrate, the flexible substrate comprising a first face and a second face that are opposite to each other, a display element being on the first face, a protective film layer being on the second face; wherein the method comprises:
providing a mask; and
irradiating towards one side of the protective film layer away from the flexible substrate through the mask by using light to form a groove on the protective film layer.

2. The method according to claim 1, wherein the irradiating towards one side of the protective film layer away from the flexible substrate through the mask by using light to form a groove on the protective film layer comprises:
irradiating one side of the protective film layer away from the flexible substrate through the mask by using a laser beam to form the groove on the protective film layer.

3. The method according to claim 2, wherein a transmittance of the mask for the laser beam gradually decreases along a direction away from a center of the mask.

4. The method according to claim 2, wherein the mask has a plurality of gray scale regions arranged along a direction away from a center of the mask, a transmittance of the plurality of gray scale regions for the laser beam gradually decreasing along an arrangement direction of the plurality of gray scale regions.

5. The method according to claim 2, wherein the laser beam is an ultraviolet UV laser beam.

6. The method according to claim 1, wherein the irradiating towards one side of the protective film layer away from the flexible substrate through the mask by using light to form a groove on the protective film layer comprises:
forming the groove on the protective film layer by a patterning process.

7. The method according to claim 1, wherein a width of the groove in a direction parallel to the flexible substrate and away from the display element is greater than or equal to 0.8 mm, and less than or equal to 2 mm.

8. The method according to claim 1, wherein a connection layer is between the flexible substrate and the protective film layer, and the groove has a depth that is less than a sum of a thickness of the protective film layer and a thickness of the connection layer.

9. (canceled)

10. A display apparatus, comprising:
a flexible substrate, the flexible substrate comprising a first face and a second face that are opposite to each other, a display element being on the first face, a protective film layer being on the second face;
wherein a groove is on a face of the protective film layer away from the flexible substrate.

11. The display apparatus according to claim 10, wherein a width of the groove in a direction parallel to the flexible substrate and away from the display element is greater than or equal to 0.8 mm, and less than or equal to 2 mm.

12. The display apparatus according to claim 10, wherein a connection layer is between the flexible substrate and the protective film layer, and the groove has a depth that is less than a sum of a thickness of the protective film layer and a thickness of the connection layer.

13-15. (canceled)

16. The method according to claim 5, wherein the laser beam is a carbon dioxide CO2 laser beam.

17. The method according to claim 1, wherein the irradiating towards one side of the protective film layer away from the flexible substrate through the mask by using light to form a groove on the protective film layer comprises:
irradiating one side of the protective film layer away from the flexible substrate through the mask by using a laser beam to form the groove on the protective film layer, an inner side face of the groove being arc-shaped;
wherein, a transmittance of the mask for the laser beam gradually decreases along a direction away from a center of the mask;
a connection layer is between the flexible substrate and the protective film layer, the groove has a depth that is less than a sum of a thickness of the protective film layer and a thickness of the connection layer; and
the first face of the flexible substrate includes a bending region, an orthographic projection of the groove on the first face overlapping the bending region, and the first face of the flexible substrate includes a wiring region, the bending region being within the wiring region.

18. The display apparatus according to claim 10, wherein the first face of the flexible substrate includes a bending region, an orthographic projection of the groove on the first face overlapping the bending region.

19. The display apparatus according to claim 18, wherein the first face of the flexible substrate includes a wiring region, the bending region being within the wiring region.

20. The display apparatus according to claim 10, wherein an inner side face of the groove is arc-shaped.

21. The display apparatus according to claim 10, wherein an inner side face of the groove is step-shaped.

22. The display apparatus according to claim 10, wherein the groove is a rectangular groove.

23. The display apparatus according to claim 10, wherein the first face of the flexible substrate includes a bending region, an orthographic projection of the groove on the first face overlapping the bending region, and the first face of the flexible substrate includes a wiring region, the bending region being within the wiring region; and
a connection layer is between the flexible substrate and the protective film layer, the groove has a depth that is less than a sum of a thickness of the protective film layer and a thickness of the connection layer, and the inner side face of the groove is arc-shaped.

24. A terminal, comprising a display apparatus, wherein the display apparatus comprises a flexible substrate, the flexible substrate comprising a first face and a second face that are opposite to each other, a display element being on the first face, a protective film layer being on the second face; wherein a groove is on a face of the protective film layer away from the flexible substrate.
